(19) United States
(12) Patent Application Publication
(10) Pub. No.: US 2025/0386538 A1
(43) Pub. Date: Dec. 18, 2025

(54) SEMICONDUCTOR DEVICE

(71) Applicants: Kabushiki Kaisha Toshiba, Kawasaki-shi (JP); Toshiba Electronic Devices & Storage Corporation, Kawasaki-shi (JP)

(72) Inventor: Yasunobu SAITO, Inagi Tokyo (JP)

(21) Appl. No.: 19/313,718

(22) Filed: Aug. 28, 2025

Related U.S. Application Data
(63) Continuation of application No. PCT/JP2023/034091, filed on Sep. 20, 2023.

(51) Int. Cl. H10D 30/47; H10D 62/10; H10D 62/60; H10D 62/824; H10D 64/00

(52) U.S. Cl. CPC H10D 30/475; H10D 62/102; H10D 62/60; H10D 62/824; H10D 64/112

(57) ABSTRACT

According to the present embodiment, a second electrode, a third electrode, an electrode part, and a region. The second nitride semiconductor layer is a nitride semiconductor layer located on the first nitride semiconductor layer and having a larger bandgap than that of the first nitride semiconductor layer. The first electrode is located on the second nitride semiconductor layer. The second electrode is located on the second nitride semiconductor layer. The third electrode is located on the second nitride semiconductor layer between the first electrode and the second electrode. The electrode part is electrically connected to at least any of the first electrode, the second electrode, and the third electrode and is arranged above the third electrode. The region is a region separate from the third electrode and including negative fixed charges implanted therein in the second nitride semiconductor layer.

### CROSS-REFERENCE TO THE RELATED APPLICATIONS

This application is a continuation application of International Application No. PCT/JP2023/034091, filed on Sep. 20, 2023, the entire contents of which are incorporated herein by reference.

### FIELD

The embodiments of the present invention relate to a semiconductor device.

### BACKGROUND

It is known that a semiconductor device such as a transistor or a diode using a nitride semiconductor has a higher operating voltage and a higher current density than conventional semiconductor devices.

Furthermore, field plates are increasingly arranged to relax an electric field. However, there is a risk that a peak of the field intensity remains at end portions of the field plates and the breakdown voltage is decreased.

### BRIEF DESCRIPTION OF DRAWINGS

FIG. 1 is a schematic sectional view of a semiconductor device according to the present embodiment.

FIG. 2 is a sectional view illustrating a detailed configuration example of a first region 32.

FIG. 3 is a sectional view in a case where production margin of the first region 32 is considered.

FIG. 4 is a diagram schematically illustrating the density of two-dimensional electron gas and the electric field relaxation effect.

FIG. 5 is a schematic sectional view of a semiconductor device 1 according to a second embodiment.

### DETAILED DESCRIPTION

According to the present embodiment, a semiconductor device includes a first nitride semiconductor layer, a second nitride semiconductor layer, a first electrode, a second electrode, a third electrode, an electrode part, and a region. The second nitride semiconductor layer is a nitride semiconductor layer located on the first nitride semiconductor layer and having a larger bandgap than that of the first nitride semiconductor layer. The first electrode is located on the second nitride semiconductor layer. The second electrode is located on the second nitride semiconductor layer. The third electrode is located on the second nitride semiconductor layer between the first electrode and the second electrode. The electrode part is electrically connected to at least any of the first electrode, the second electrode, and the third electrode and is arranged above the third electrode. The region is a region separate from the third electrode and including negative fixed charges implanted therein in the second nitride semiconductor layer.

Embodiments of the present invention will now be explained below with reference to the drawings. In the following embodiments, while characteristic configurations and operations of a semiconductor device will be explained, configurations and operations omitted in the following descriptions may be included in the semiconductor device.

### First Embodiment

Embodiments of the present invention will be explained below with reference to the drawings. The drawings are schematic and conceptual, and the relation between the thickness and the width of each part, the ratio of size among the parts, and the like do not necessarily match those of actual products. Even in a case where the same parts are represented, the dimensions and the ratios thereof are represented differently depending on the drawings in some cases. In the specification of the present application and the respective drawings, the same elements as those already explained are denoted by like reference characters and detailed explanations thereof are omitted as appropriate.

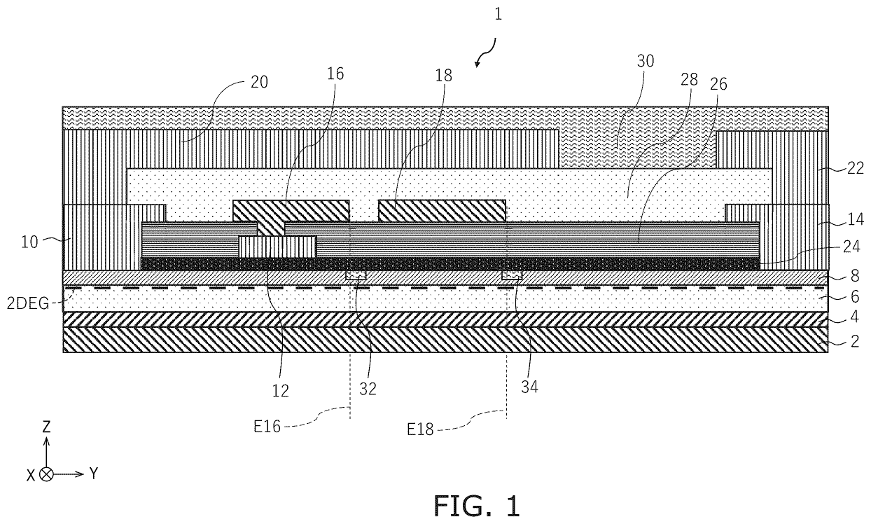

FIG. 1 is a schematic sectional view of a semiconductor device 1 according to the present embodiment. This semiconductor device 1 is, for example, a HEMT (High Electron Mobility Transistor) using a nitride semiconductor such as GaN (gallium nitride), AlGaN (aluminum gallium nitride), or InGaN (indium gallium nitride). The semiconductor device 1 according to the present embodiment has a transverse device structure using a nitride semiconductor.

The semiconductor device 1 includes a substrate 2, a buffer layer 4, a first nitride semiconductor layer 6, a second nitride semiconductor layer 8, a source electrode (one example of a first electrode) 10, a gate electrode (one example of a third electrode) 12, a drain electrode (one example of a second electrode) 14, a gate field-plate electrode part 16 (one example of a first electrode part), a field-plate electrode part (one example of a second electrode part) 18, a source field-plate electrode part (one example of a third electrode part) 20, a drain field-plate electrode part 22 (one example of a fourth electrode part), an insulating film 24, a first insulating layer 26, a second insulating layer 28, a third insulating layer 30, a first region 32, and a second region 34. In the embodiments, an X-direction, a Y-direction perpendicularly intersecting with the X-direction, and a Z-direction perpendicularly intersecting with the X-direction and the Y-direction are defined. The Z-direction is a direction in which the substrate 2, the buffer layer 4, the first nitride semiconductor layer 6, and the second nitride semiconductor layer 8 are stacked. In some cases, an upper direction in the drawings of the present specification is described as “upper” and a lower direction in the drawings is described as “lower”. In the present specification, the concepts of “upper” and “lower” are not necessarily terms representing a relation with the direction of gravity.

As the substrate 2, a Si (silicon) substrate or a sapphire substrate is used, for example. The buffer layer 4 is provided on the substrate 2. The buffer layer 4 reduces lattice mismatch with the substrate 2. The substrate 2 and the buffer layer 4 are referred to also as “underlying layers”.

The first nitride semiconductor layer 6 is provided on the buffer layer 4. The first nitride semiconductor layer 6 is, for example, undoped Al_{X}Ga_{1-X}N (0≤X<1). More specifically, the first nitride semiconductor layer 6 is, for example, undoped GaN. The first nitride semiconductor layer 6 functions as a channel layer. The thickness of the first nitride semiconductor layer 6 is, for example, not less than 1 μm and not more than 10 μm.

The second nitride semiconductor layer 8 is provided on the first nitride semiconductor layer 6. The bandgap of the second nitride semiconductor layer 8 is configured to be larger than that of the first nitride semiconductor layer 6. The second nitride semiconductor layer 8 is, for example, undoped Al_{Y}Ga_{1-Y}N (0<Y≤1, X<Y). More specifically, the second nitride semiconductor layer 8 is, for example, undoped Al_{0.2}Ga_{0.8}N. The second nitride semiconductor layer 8 functions as a barrier layer. The thickness of the second nitride semiconductor layer 8 is, for example, 15 nm to 50 nm and is preferably 30 nm.

A heterojunction interface is provided between the first nitride semiconductor layer 6 and the second nitride semiconductor layer 8. At the time of an on-operation of the semiconductor device 1, two-dimensional electron gas (2DEG) is formed on the heterojunction interface and becomes carriers. The substate 2, the buffer layer 4, the first nitride semiconductor layer 6, and the second nitride semiconductor layer 8 are arranged in parallel to a plane including an X-axis parallel to the X-direction and a Y-axis parallel to the Y-direction, that is, an X-Y plane. An interface between the substrate 2 and the buffer layer 4, an interface between the buffer layer 4 and the first nitride semiconductor layer 6, and an interface between the first nitride semiconductor layer 6 and the second nitride semiconductor layer 8 are provided in parallel to the X-Y plane. The Y-direction is a direction in which the carriers of the semiconductor device 1 being a HEMT flow. In other words, the Y-direction is the gate length direction of the semiconductor device 1. The X-direction is the gate width direction of the semiconductor device 1.

The source electrode 10 is provided on the second nitride semiconductor layer 8. The source electrode 10 functions as a source electrode of the semiconductor device 1. The source electrode 10 is configured, for example, to include a stacked structure of titanium (Ti) and aluminum (AI).

The drain electrode 14 is provided on the second nitride semiconductor layer 8. The drain electrode 14 functions as a drain electrode of the semiconductor device 1. The drain electrode 14 is configured, for example, to include a stacked structure of titanium (Ti) and aluminum (Al). The distance between the source electrode 10 and the drain electrode 14 is, for example, not less than 5 μm and not more than 30 μm.

The insulating film 24 is provided between the source electrode 10 and the drain electrode 14 on the second nitride semiconductor layer 8. The insulating film 24 is in direct contact with the second nitride semiconductor layer 8. The insulating film 24 is configured to include an insulating material. For example, the insulating material is silicon nitride (SiN). However, the material included in the insulating film 24 is not limited thereto. For example, the insulating material may be silicon oxide (SiO), silicon oxynitride (SiON), silicon oxide containing carbon (SiOC), aluminum nitride (AlN), or aluminum oxide (AIO). The thickness of the insulating film 24 in the Z-direction is, for example, 20 nm to 30 nm.

The gate electrode 12 is provided on the second nitride semiconductor layer 8 between the source electrode 10 and the drain electrode 14. More specifically, the gate electrode 12 is provided on the insulating film 24 between the second nitride semiconductor layer 8 and the first insulating layer 26. The gate electrode 12 includes, for example, a stacked structure of nickel (Ni) and gold (Au), titanium nitride (TiN), or polycrystalline silicon (Poly-Si). It is preferable that the bottom surface of the gate electrode 12 is in contact with the insulating film 24.

The first insulating layer 26 is provided on the gate electrode 12 on the insulating film 24. The first insulating layer 26 is configured, for example, to include silicon nitride (SiN). However, the material included in the first insulating layer 26 is not limited thereto. For example, the first insulating layer 26 may be configured to include silicon oxide (SiO), silicon oxynitride (SiON), silicon oxide containing carbon (SiOC), or aluminum nitride (AlN), aluminum oxide (AIO). The thickness of the first insulating layer 26 in the Z-direction is, for example, 200 nm to 300 nm.

The gate field-plate electrode part 16 has a portion extending along the upper surface of the first insulating layer 26 and has one end electrically connected to the gate electrode 12. That is, one end of the gate field-plate electrode part 16 is electrically connected to the upper surface of the gate electrode 12. The gate field-plate electrode part 16 extends upward in the first insulating layer 26 and extends in the gate length direction on the first insulating layer 26. However, the form of the gate field-plate electrode part 16 is not limited thereto. The gate field-plate electrode part 16 is used to relax the electric field in the semiconductor device 1. The gate field-plate electrode part 16 is, for example, a structure including a stacked structure of Al (aluminum), Cu (copper), W (tungsten), and TiN (titanium nitride) or a stacked structure of titanium (Ti) and aluminum (Al).

The field-plate electrode part 18 has a portion extending along the upper surface of the first insulating layer 26 between the gate field-plate electrode part 16 and the drain electrode 14. That is, the field-plate electrode part 18 is provided on the first insulating layer 26 between the insulating film 24 and the second insulating layer 28. The field-plate electrode part 18 is electrically connected to, for example, the source electrode 10 using, for example, a line (not illustrated) provided in the gate width direction. The field-plate electrode part 18 is used to relax the electric field in the semiconductor device 1. The field-plate electrode part 18 is, for example, a structure including a stacked structure of Al (aluminum), Cu (copper), W (tungsten), and TIN (titanium nitride) or a stacked structure of titanium (Ti) and aluminum (Al).

The second insulating layer 28 is provided on the first insulating layer 26, on the gate field-plate electrode part 16, and on the field-plate electrode part 18. The second insulating layer 28 is configured to include, for example, silicon dioxide (SiO₂) being silicon oxide. Alternatively, the second insulating layer 28 may be configured to include silicon monoxide (SiO) being silicon oxide, silicon oxynitride (SiON), silicon oxide containing carbon (SiOC), aluminum nitride (AlN), aluminum oxide (AIO), or the like. However, the material included in the second insulating layer 28 is not limited thereto.

The source field-plate electrode part 20 has one end electrically connected to the source electrode 10, and has a portion extending on the gate field-plate electrode part 16 and on the field-plate electrode part 18 along the upper surface of the first insulating layer 26. That is, one end of the source field-plate electrode part 20 is provided, for example, on the source electrode 10 and is electrically connected to the source electrode 10. The source field-plate electrode part 20 is provided on the source electrode 10, on the gate electrode 12, on the gate field-plate electrode part 16, on the field-plate electrode part 18, on the insulating film 24, and on the second insulating layer 28 between the first insulating layer 26 and the third insulating layer 30. The source field-plate electrode part 20 is used to relax the electric field in the semiconductor device 1. The source field-plate electrode part 20 is, for example, a structure including a stacked structure of Al (aluminum), Cu (copper), W (tungsten), and TiN (titanium nitride) or a stacked structure of titanium (Ti) and aluminum (Al).

The drain line electrode part 22 has one end electrically connected to the drain electrode 14. The drain line electrode part 22 is provided, for example, on the second insulating layer 28. The drain field-plate electrode part 22 is used to relax the electric field in the semiconductor device 1. The drain field-plate electrode part 22 is, for example, a structure including a stacked structure of Al (aluminum), Cu (copper), W (tungsten), and TIN (titanium nitride) or a stacked structure of titanium (Ti) and aluminum (Al).

The first region 32 and the second region 34 are negative charge regions that is configured in the second nitride semiconductor layer 8 according to positions of end portions E16 and E18 of the electrode parts 16 and 18 on the side of the drain electrode 14 and that is separate from the gate electrode 12. That is, the first region 32 and the second region 34 are regions that are separate from the gate electrode 12 in the second nitride semiconductor layer 8 and that include negative fixed charges implanted therein. Ranges of the first region 32 and the second region 34 in the y-direction are each, for example, not less than 0.3 μm and not more than 0.6 μm.

More specifically, the first region 32 is formed at the end portion E16 of the gate field-plate electrode part 16 on the side of the drain electrode 14 in the second nitride semiconductor layer 8. The first region 32 is a region including halogen elements implanted therein. The halogen elements are, for example, fluorine (F) or chlorine (Cl). That is, the first region 32 is a halogen-implanted region and is a region including negative fixed charges implanted by annealing processing. Since the halogen elements are diffused also in the gate length direction (the y-direction) by the annealing processing, the charges gradually change and electric field changes are also gentle. The implantation of the halogen elements is performed, for example, by a CDE (Chemical Dry Etching) method using gas containing CF4.

As described above, electric field concentration at ends of the gate electrode 12 is relaxed by the gate field-plate electrode part 16. Meanwhile, electric field concentration remains at the end portion E16 of the gate field-plate electrode part 16 on the side of the drain electrode 14. Therefore, the first region 32 is used to relax the electric field concentration occurring at the end portion E16. This further improves the breakdown voltage of the semiconductor device 1.

The second region 34 is formed at the end portion E18 of the field-plate electrode part 18 on the side of the drain electrode 14 in the second nitride semiconductor layer 8. The second region 34 is a region including halogen elements implanted therein. The halogen elements are, for example, fluorine (F) or chlorine (Cl). That is, the second region 34 is a halogen-implanted region and is a region including negative fixed charges implanted by annealing processing. Since the halogen elements are diffused also in the gate length direction (the y-direction) by the annealing processing, the charges gradually change and electric field changes are also gentle. The implantation of the halogen elements is performed, for example, by the CDE (Chemical Dry Etching) method using gas containing CF4.

As described above, electric field concentration is relaxed by the field-plate electrode part 18. Meanwhile, electric field concentration remains at the end portion E18 of the field-plate electrode part 18 on the side of the drain electrode 14. Therefore, the second region 34 is used to relax the electric field concentration occurring at the end portion E18. This further improves the breakdown voltage of the semiconductor device 1.

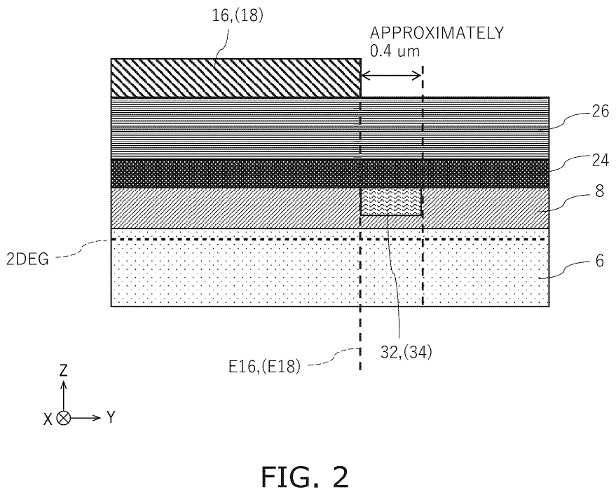

Meanwhile, if the ranges of the first region 32 and the second region 34 are enlarged, the two-dimensional electron gas is affected and the on-resistance is increased. Therefore, the ranges of the first region 32 and the second region 34 are limited to those illustrated in FIG. 2.

FIG. 2 is a sectional view illustrating a detailed configuration example of the first region 32. While an example of the first region 32 is described in FIG. 2, the second region 34 also has the same configuration. As illustrated in FIG. 2, the first region 32 is constituted to be flush with the upper surface of the second nitride semiconductor layer 8, for example, on the side of the insulating film 24.

A range in which the first region 32 is constituted is set based on a peak position of an electric field generated by the gate field-plate electrode part 16. This peak position is the end portion E16 of the gate field-plate electrode part 16 on the side of the drain electrode 14. This peak steeply rises at the end portion E16 and decreases while trailing toward the drain electrode 14. Accordingly, a length of the first region 32 along the surface of the second nitride semiconductor layer 8 is, for example, 0.4 μm from the end portion E16 of the drain electrode 14. This width is set according to a field concentrated region. The first region 32 is arranged at a position away from the gate electrode 12 to prevent negative fixed charges of the first region 32 from affecting the switching operation of the gate electrode 12.

The depth thereof is a range not reaching the two-dimensional electron gas (2DEG). For example, the depth of the first region 32 is a range within the second nitride semiconductor layer 8. The concentration of the implanted halogen elements can be changed according to an electric field generated by the field-plate electrode part 18. For example, the concentration of the implanted halogen elements in the first region 32 is, for example, about the maximum concentration of the two-dimensional electron gas (2DEG). Activation rates of the first region 32 and the second region 34 are equal to or less than 50%. Accordingly, even when the halogen elements at about the concentration of the two-dimensional electron gas (2DEG) are implanted, decrease of the two-dimensional electron gas in the implanted portion is equal to or less than 50% and the influence on the on-resistance is also suppressed.

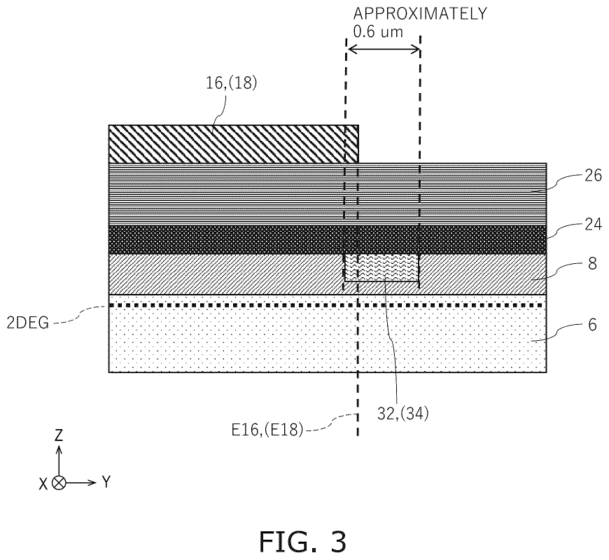

FIG. 3 is a sectional view in a case where production margin of the first region 32 is considered. While an example of the first region 32 is described in FIG. 3, a configuration example of the second region 34 is the same. Since the peak of the electric field becomes the largest at the end portion E16, the electric field relaxation effect decreases if the first region 32 is away from the end portion E16 toward the drain electrode 14. Therefore, the first region 32 is constituted to be broadened, for example, by approximately 0.2 μm toward the gate electrode as production margin. This suppresses the first region 32 from being away from the end portion E16 toward the drain electrode 14.

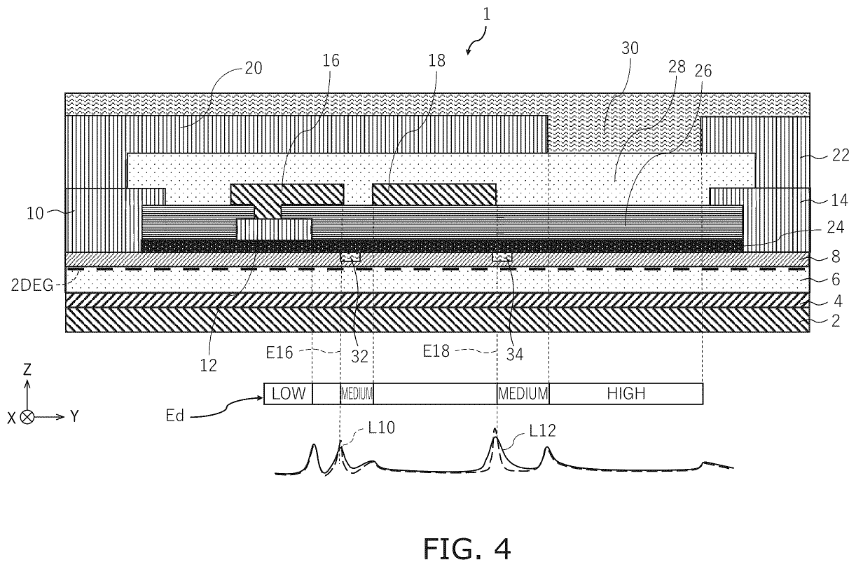

FIG. 4 is a diagram schematically illustrating the density of the two-dimensional electron gas and the electric field relaxation effect. A schematic diagram Ed is a diagram schematically indicating the density of the two-dimensional electron gas during an operation of the semiconductor device 1. In FIG. 4, the density is represented by three levels of “low”, “medium”, and “high”. The density of the two-dimensional electron gas increases in the order of “low”, “medium”, and “high”. A line L10 indicates field intensities in a case where the first region 32 and the second region 34 are not included. A line L12 indicates field intensities in a case where the first region 32 and the second region 34 are included. The vertical axis corresponds to the field intensity and the horizontal axis corresponds to the Y-coordinate.

As illustrated in FIG. 4, the density of the two-dimensional electron gas is at a “high” level between an end portion of the source field-plate electrode part 20 on the drain side and an end portion of the drain field-plate electrode part 22 on the source side. The density is at a “medium” level between the end portion E16 of the gate field-plate electrode part 16 on the side of the drain electrode 14 and an end portion of the field-plate electrode part 18 on the side of the gate electrode 12. Similarly, the density is at a “medium” level between the end portion E18 of the field-plate electrode part 18 on the side of the drain electrode 14 and an end portion of the source field-plate electrode part 20 on the drain side. The density is at a “low” level at a portion under the gate electrode 12.

At the time of an operation of the semiconductor device 1, a voltage (a drain voltage) is applied between the drain electrode 14 and the gate electrode 12. The field intensity in the case where the first region 32 and the second region 34 are not included is as indicated by the line L10 and the electric field is likely to be concentrated at the end portion E16 of the gate field-plate electrode part 16 on the side of the drain electrode 14 and the end portion E18 of the field-plate electrode part 18 on the side of the drain electrode 14.

In contrast thereto, according to the present embodiment, since the first region 32 and the second region 34 having negative fixed charges are constituted at the end portion E16 and the end portion E18 being end portions on the side of the drain electrode 14, the electric fields concentrated at the end portion E16 and the end portion E18 are relaxed as indicated by the line L12. In this way, concentration of the electric fields generated at the end portion E16 and the end portion E18 is relaxed by the first region 32 and the second region 34, and the breakdown voltage of the semiconductor device 1 is further improved.

As described above, according to the present embodiment, the semiconductor device 1 of the present embodiment is configured in such a manner that the electrode parts 16 and 18 are electrically connected to at least any of the source electrode 10, the gate electrode 12, and the drain electrode 14, are arranged above the gate electrode 12, and have the end portions E16 and E18 at positions closer to the drain electrode 14 than an end portion of the gate electrode 12 on the side of the drain electrode 14, and the first region 32 and the second region 34 are constituted as negative charge regions separate from the gate electrode 12 according to the positions of the end portions E16 and E18 in the second nitride semiconductor layer 8. Accordingly, while influences of negative charges on the gate electrode 12 are suppressed, concentration of the electric fields generated at the end portion E16 and the end portion E18 is relaxed and the breakdown voltage of the semiconductor device 1 is further improved.

### Second Embodiment

The semiconductor device 1 according to a second embodiment is different from the semiconductor device 1 according to the first embodiment in that the concentration of the implanted halogen elements in a region where the halogen elements are implanted is changed according to the magnitude of a peak of the electric field. Differences from the semiconductor device 1 according to the first embodiment are described below.

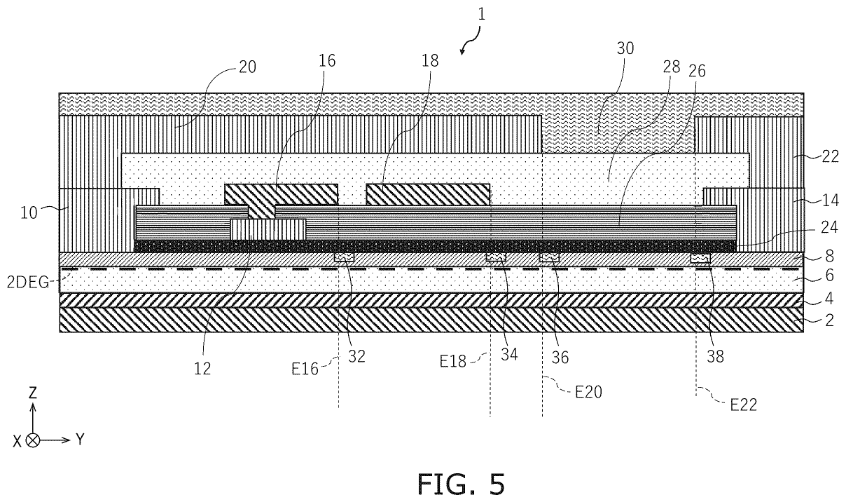

FIG. 5 is a schematic sectional view of the semiconductor device 1 according to the second embodiment. In FIG. 5, the semiconductor device 1 according to the second embodiment is different from that according to the first embodiment in that a third region 36 is additionally constituted at an end portion E20 of the source field-plate electrode part 20 on the drain side and that a fourth region 38 is additionally constituted at an end portion E22 of the drain line electrode part 22.

The concentrations of the implanted halogen elements in the first region 32, the second region 34, the third region 36, and the fourth region 38 are changed according to the magnitude of a peak of the electric field. For example, the magnitude of a peak of the electric field in a case where the first region 32, the second region 34, the third region 36, and the fourth region 38 are not included increases in the order of at the end portion E22, at the end portion E20, at the end portion E16, and at the end portion E18. Therefore, the concentration of the implanted halogen elements also increases in the order of in the fourth region 38, in the third region 36, in the first region 32, and in the second region 34. At least any of the first region 32, the second region 34, the third region 36, and the fourth region 38 according to the present embodiment corresponds to a region.

This enables concentration of the electric field generated at the end portion E22, the end portion E20, the end portion E16, and the end portion E18 to be relaxed to the same degree and enables the concentration of the implanted halogen elements to be suppressed, and the influence on the on-resistance of the semiconductor device 1 is also suppressed.

As described above, according to the present embodiment, the gate field-plate electrode part 16, the field-plate electrode part 18, the source field-plate electrode part 20, and the drain line electrode part 22 each have a portion extending along a direction (the y-direction) along the upper surface of the second nitride semiconductor layer 8, and the first region 32, the second region 34, the third region 36, and the fourth region 38 are constituted according to the positions of the end portions E16, E18, E20, and E22 on the side closer to the second electrode. Accordingly, the electric field generated at the positions of the end portions E16, E18, E20, and E22 can be relaxed and the breakdown voltage of the semiconductor device 1 can be increased. Furthermore, since the concentration of the implanted halogen elements is changed according to the magnitude of the field intensities generated at the positions of the end portions E16, E18, E20, and E22, the implantation of the halogen elements can be suppressed. Therefore, the breakdown voltage of the semiconductor device 1 can be increased while increase in the on-resistance is suppressed.

While certain embodiments of the present invention have been described, these embodiments have been presented by way of example only, and are not intended to limit the scope of the invention. The novel embodiments described herein may be embodied in a variety of other forms, and various omissions, substitutions, and changes may be made without departing from the spirit of the invention. These embodiments and modifications thereof would fall within the scope and spirit of the 10 invention, and would fall within the invention described in the accompanying claims and their equivalents.

1. A semiconductor device comprising:
a first nitride semiconductor layer;
a second nitride semiconductor layer located on the first nitride semiconductor layer and having a larger bandgap than that of the first nitride semiconductor layer;
a first electrode located on the second nitride semiconductor layer;
a second electrode located on the second nitride semiconductor layer;
a third electrode located on the second nitride semiconductor layer between the first electrode and the second electrode;
an electrode part electrically connected to at least any of the first electrode, the second electrode, and the third electrode and arranged above the third electrode; and
a region separate from the third electrode and including negative fixed charges implanted therein in the second nitride semiconductor layer.

2. The device of claim 1, wherein
the electrode part includes an end portion at a position closer to the second electrode than an end portion of the third electrode on a side of the second electrode, and
the region is a region including halogen elements implanted therein.

3. The device of claim 2, wherein the region is constituted according to a position of a first end portion of the electrode part on a side of the second electrode, the halogen elements are at least either fluorine (F) or chlorine (Cl), and the region is a region annealed after the halogen elements are implanted therein.

4. The device of claim 1, wherein the region is constituted to be flush with an upper surface of the second nitride semiconductor layer.

5. The device of claim 1, wherein the region is constituted to include a first position where a first direction perpendicular to an upper surface of the second nitride semiconductor layer along the first end portion intersects with the upper surface of the second nitride semiconductor layer.

6. The device of claim 5, wherein the region is parallel to the upper surface of the second nitride semiconductor layer, and a first range of the region in a second direction perpendicular to the first direction from a side of the first electrode to the first position is constituted to be narrower than a second range thereof from the first position to a side of the second electrode.

7. The device of claim 6, wherein a distance between the first electrode and the second electrode in the second direction is not less than 5 μm and not more than 30 μm, and a range of the region in the second direction is not less than 0.3 μm and not more than 0.6 μm.

8. The device of claim 2, wherein the region is constituted in plural, and implantation densities of halogen elements differ according to positions of first end portions.

9. The device of claim 8, wherein the region is constituted in plural, and implantation densities of halogen elements are constituted to be higher as a magnitude of an electric field to be generated is larger.

10. The device of claim 1, further comprising:
an insulating film located between the first electrode and the second electrode on the second nitride semiconductor layer, and being in contact with the second nitride semiconductor layer; and
a first insulating layer located on the insulating film between the first electrode and the third electrode, on the insulating film between the third electrode and the second electrode, and on the third electrode, wherein
the third electrode is located on the insulating film between the first electrode and the second electrode.

11. The device of claim 10, comprising a plurality of the electrode parts, and further comprising a first electrode part comprising a portion extending along an upper surface of a first insulating layer and having one end electrically connected to the third electrode.

12. The device of claim 11, further comprising a second electrode part comprising a portion extending along an upper surface of a first insulating layer between the first electrode part and the second electrode.

13. The device of claim 12, further comprising a third electrode part having one end electrically connected to the first electrode, and comprising a portion extending on the first electrode part and on the second electrode part along the upper surface of the first insulating layer.

14. The device of claim 13, further comprising a fourth electrode part having one end electrically connected to the second electrode, and comprising a portion extending along the upper surface of the first insulating layer.

15. The device of claim 14, wherein the region is constituted according to a position of an end portion of a portion extending along the upper surface of the first insulating layer on a side closer to the second electrode in at least any of the first electrode part, the second electrode part, the third electrode part, and the fourth electrode part.
